(19) United States
(12) Patent Application Publication
(10) Pub. No.: US 2017/0123007 A1
(43) Pub. Date: May 4, 2017

(54) METHOD AND APPARATUS FOR DETECTING INTERTURN FAULTS, AND ELECTRICAL MACHINE

(71) Applicant: Siemens Aktiengesellschaft, Munich (DE)

(72) Inventors: Ralf MERTE, Dortmund (DE); Christian STAUBACH, Marl (DE)

(73) Assignee: SIEMENS AKTIENGESELLSCHAFT, Munich (DE)

(21) Appl. No.: 15/306,542

(22) PCT Filed: Mar. 31, 2015
(86) PCT No.: PCT/EP2015/057060

§ 371 Date: Oct. 25, 2016

(30) Foreign Application Priority Data
May 6, 2014 (EP) 14167158.6

(51) Int. Cl. G01R 31/34; H02K 11/26

(52) U.S. Cl. CPC G01R 31/346; G01R 31/343; H02K 11/26

(57) ABSTRACT

An apparatus for detecting interturn faults inside a rotor winding of a rotating electrical machine with a measuring device. The measuring device has at least two measuring coils oriented differently in space such that, in the case of a measuring device oriented with respect to the rotor winding, a voltage is induced inside the first measuring coil by a first directional component of the magnetic flux density B of the rotating electrical machine and a different voltage is induced inside the further measuring coil by a further directional component of this magnetic flux density B, which directional component differs from the first directional component. The at least two measuring coils oriented differently in space are arranged together on a head part of the measuring device, where interturn faults present on the rotor winding are detected based on temporal voltage profiles of the voltages induced in the two measuring coils.

### CROSS REFERENCE TO RELATED APPLICATIONS

This application is the U.S. National Stage of International Application No. PCT/EP2015/057060 filed Mar. 31, 2015, and claims the benefit thereof. The International Application claims the benefit of European Application No. EP14167158 filed May 6, 2014. All of the applications are incorporated by reference herein in their entirety.

### FIELD OF INVENTION

The invention relates to an apparatus for detecting interturn faults inside a rotor winding of a rotating electrical machine by means of a measuring device, wherein the measuring device comprises at least two measuring coils that are oriented differently in space in such a manner that, in the case of a measuring device accordingly oriented with respect to the rotor winding, a voltage induction can be generated inside the first measuring coil by means of a first directional component of the magnetic flux density B of the rotating electrical machine, and a different voltage induction can be generated inside the further measuring coil by means of a further directional component of this magnetic flux density B, which directional component differs from the first directional component.

The invention additionally relates to an electrical machine, in particular a generator, having a stator and a rotor rotating therein.

The invention also relates to a method for detecting interturn faults inside a rotor winding of a rotating electrical machine

### BACKGROUND OF INVENTION

In particular, methods of the generic type for detecting interturn faults, especially inside rotor windings, are known from the prior art in connection with large, rotating electrical machines such as, for example, generators, turbogenerators or the like.

Such interturn faults are caused, for example, by defective insulations on electrical conductive elements in rotor windings, as a result of which individual windings are no longer properly insulated in relation to each other. To that extent, interturn faults inside rotor windings of large, rotating electrical machines may result in permanent, negative impairment of the operation of the latter. For example, thermal asymmetry may occur, which, in turn, may result in an increased level of vibration of the rotating rotor, or in distortions of the magnetic field, to the extent of a total failure of the entire rotating electrical machine. For these reasons alone, it appears to be absolutely essential to detect such interturn faults inside a rotor winding in as timely a manner as possible, in order to avoid potentially greater damage to the rotating electrical machine.

Already known from the prior art are a plurality of methods by means of which such interturn faults inside rotor windings of rotating electrical machines can be detected. Basically, these methods can be divided into two different method types, namely, on the one hand, a first method type, in which detection of interturn faults is performed during operation of a rotating electrical machine, i.e. online, and, on the other hand, a further method type, in which detection of interturn faults is performed while the rotating electrical machine is at a standstill, i.e. offline. The greatest disadvantage of the offline method type is probably that, owing to the absence of electrical, thermal or, especially, mechanical loads, any interturn faults that arise only when the rotating electrical machine is in operation cannot be present while the rotating electrical machine is at a standstill, or can be present only in such an indistinct manner that they cannot be detected in an operationally reliable manner by means of a corresponding standstill diagnosis. Furthermore, such a standstill diagnosis can only be performed economically at relatively long intervals of time, for example as part of servicing operations, owing to the increased amount of work that is associated therewith. To that extent, in the case of this further, offline method type, inspection of a rotor winding for interturn faults is only economically expedient in irregular cases.

The situation is entirely different with regard to the first method type, which is performed online, which to that extent can also be applied permanently, during operation. In the case of the online method type, the method that is probably the best known in this regard for permanent inspection and/or monitoring of interturn faults during operation is based on measurement of electrical flux by means of a measuring coil (flux probe) that is disposed in an air gap between the circumferential surface of the rotor and an inner surface of the stator that is complementary to the latter, and oriented in such a manner that voltages can be induced in the measuring coil by the moving rotor magnetic field.

The measuring coil in this case is wound or cast into a stator housing of the rotating electrical machine in such a manner that the active surface thereof is oriented radially in relation to the circumferential surface of the rotor. Consequently, only the radial component of the magnetic flux density B of the rotating electrical machine causes a voltage induction inside the measuring coil. A voltage characteristic analysis of the voltage induced in the measuring coil can be used to detect interturn faults inside the rotor winding. The sensitivity in respect of the detection of the interturn faults on the basis of this voltage characteristic analysis depends on a multiplicity of factors. Of importance in this case are the characteristic of the respective interturn fault and the position of the interturn fault inside the rotor winding. Additional influencing factors are the mode of operation of the rotating electrical machine, the effective power output, the loss factor cosφ and the sensitivity of this measuring method. To that extent, it is recommended to attain differing load points with the rotating electrical machine in operation, in order to achieve the most precise possible detection of interturn faults. This, however, is very laborious. Moreover, the voltage characteristics measured in the measuring coil may be falsified by a predominant rotor eccentricity, thereby possibly resulting in an incorrect interpretation.

Known from DE 10 2008 001 183 A1, for example, is a method for monitoring an electrodynamic machine, in which both an axial and a tangential component of a magnetic field, generated by the electrodynamic machine, are sensed and evaluated separately. Corresponding magnetic-field sensors are disposed outside of the stator housing, distributed concentrically and singly around the rotor, such that the stray magnetic field outside of the generator arrangement can be sensed.

Further, US 2009/0179663 A1 discloses a method and an apparatus for detecting interlaminar short circuits, for which at least one magnetic measuring probe, for example two or more measuring loops, disposed in differing radial planes, for measuring the ring flux, and preferably at least one magnetic measuring probe for measuring the stator flux, are provided.

The publication “Electrical Machines Fault Diagnosis by Stray Flux Analysis; Electrical Machines Design Control And Diagnosis (WEMDCD); ISBN: 978-1-4673-5656-5” describes a method for testing an electrodynamic machine, in which magnetic-field sensors are disposed in differing positions on the outside of the electrodynamic machine, in order to sense axial and tangential components of a magnetic field generated by the electrodynamic machine.

Furthermore, WO 2010/040767 A1 describes a method and an apparatus for detecting interturn faults in the core assembly of an electrical machine or of a generator, wherein there is a pick-up device having at least two detectors that are disposed at two differing radial positions, with respect to the rotor axis, in order to simultaneously measure the magnetic field, generated by the electrical machine or the generator, at these two differing radial positions. In this case, subtraction is used to determine the relative magnitude and/or the relative phase position of at least two signals, and only relative differences in the signals are recorded.

U.S. Pat. No. 6,064,172 A discloses another electrical machine, comprising a winding fault detection system that has a multiplicity of magnetic-field sensors for measuring radial components of the magnetic flux density.

### SUMMARY OF INVENTION

It is an object of the invention to further develop methods of the generic type for detecting interturn faults inside rotor windings of rotating electrical machines, so as to ensure a more reliable detection of such interturn faults.

This object of the invention is achieved by an apparatus for detecting interturn faults inside a rotor winding of a rotating electrical machine by means of a measuring device, wherein the measuring device comprises at least two measuring coils that are oriented differently in space in such a manner that, in the case of a measuring device accordingly oriented with respect to the rotor winding, a voltage induction can be generated inside the first measuring coil by means of a first directional component of the magnetic flux density B of the rotating electrical machine, and a different voltage induction can be generated inside the further measuring coil by means of a further directional component of this magnetic flux density B, which directional component differs from the first directional component, and wherein the at least two measuring coils that are oriented differently in space are jointly disposed on a head part of the measuring device in such a manner that interturn faults present on the rotor winding can be detected in dependence on voltage time characteristics of the voltages induced in the two measuring coils.

The detection of interturn faults can be significantly improved as a result of the at least two measuring coils that are oriented differently in space being jointly disposed on a head part of the measuring device.

Advantageously, for the purpose of detection, two differing voltage time characteristics of two measuring coils that are oriented differently with respect to the circumferential surface of the rotor, or rotor surface, are analyzed, thereby significantly increasing the detection accuracy. With an appropriate design of the apparatus, there is no need for any of the voltage inductions generated in the measuring coils to be based on the radial component of the magnetic flux density B generated by the electrical machine. In any case, this apparatus enables the risk of possible incorrect interpretations to be reduced considerably. Moreover, it is possible explicitly to dispense with attainment of differing load points of the electrical machine.

Advantageously, however, a voltage induction can be generated inside the first measuring coil by means of the radial component of this magnetic flux density B, such that it is possible to refer back to findings from previous empirical analyses.

The object of the invention is also achieved by a method for detecting interturn faults inside a rotor winding of a rotating electrical machine, which method is characterized in that a voltage induction is generated inside a measuring coil disposed on a head part of a measuring device by means of the radial component of the magnetic flux density B of the rotating electrical machine, a different voltage induction is generated inside a further measuring coil disposed on the head part of the measuring device by means of the axial component of this magnetic flux density B, and an additional voltage induction is generated inside a third measuring coil disposed on the head part of the measuring device by means of the tangential component of this magnetic flux density B, in order to detect interturn faults present on the rotor winding in dependence on voltage time characteristics of voltages induced in the measuring coils.

According to the invention, it is not only occurrences of a voltage induction of two measuring coils, as is known, that is used to detect interturn faults inside the rotor winding of the electrical machine. Rather, this known method type is refined in that, for the purpose of evaluating a presence of interturn faults, the voltage characteristic inside a third measuring coil is additionally analyzed. This is effected with respect to a different directional component of the magnetic flux density B generated by the electrical machine, with all measuring coils being held compactly together on a head part of the measuring device.

This makes it possible to achieve a defined increase in the sensitivity with respect to identification of interturn faults.

In particular, if the further measuring coil is disposed with respect to the first measuring coil in such a manner that a different voltage induction can be generated inside the further measuring coil by means of the axial component of this magnetic flux density B, a greater sensitivity is achieved for any identification of interturn faults.

A further improvement of the present method is achieved in that an additional voltage induction is generated inside a third measuring coil by means of the tangential component of this magnetic flux density B.

This additional voltage induction can be provided by very simple design means if the measuring device comprises a third measuring coil that is disposed, on the head part, with respect to the first measuring coil in such a manner that a voltage induction can be generated inside a third measuring coil by means of the tangential component of this magnetic flux density B.

Overall, incorrect interpretations relating to interturn faults that are also caused, for example, by a rotor eccentricity, can be reduced considerably if an additional analysis of two additional spatial direction components, with respect to the magnetic flux density B generated by the electrical machine, can be effected.

A very reliable measuring accuracy can be achieved if the measuring coils are disposed with differing orientation on the head part of the measuring device in such a manner that their surface vectors are disposed at right angles to each other. This enables the voltage characteristics induced in the three measuring coils, with respect to the magnetic flux density components in the radial, axial or tangential direction, to be generated in a reliable manner and made available for further analysis purposes.

The apparatus can be of a simple design configuration if the measuring coils are disposed on a cubical element of the measuring device.

Advantageously, the apparatus also comprises an analysis device, by means of which the voltage inductions generated by the radial, axial and/or tangential components can be analyzed jointly.

In particular, the method according to the invention can be implemented directly by means of this apparatus.

The object of the invention is also achieved by an electrical machine, in particular a generator, having a stator and a rotor rotating therein, wherein the electrical machine is distinguished by the apparatus described here.

The present invention, and in particular the electrical machine according to the invention, thus renders possible sensitive detection, testing and/or online monitoring of interturn faults on rotors by means of flux measurement that is dependent on direction in space.

The achievable advantages of this flux measurement, dependent on direction in space, had already been analyzed in detail by means of theoretical calculation models based on the finite element method. It was found in this case that, depending on the position of the interturn fault inside the rotor winding, and on the operated load point of the electrical machine, the evaluation, in particular of the radial or tangential component, has a greater sensitivity for any identification of interturn faults. Owing to the use of the flux measurement that is dependent on direction in space, all components of the magnetic flux density are implicitly sensed, and monitoring of the vector quantity of the magnetic field strength is possible.

Further features, effects and advantages of the present invention are explained on the basis of the accompanying drawing and the description that follows, in which an apparatus according to the invention, for detecting interturn faults inside a rotor winding, are exemplarily represented and described.

### BRIEF DESCRIPTION OF THE DRAWINGS

In the drawing:

FIG. 1 shows, schematically, a partial view of a measuring device of the present apparatus, mounted on a stator of an electrical machine;

FIG. 2 shows, schematically, a perspective view of the measuring device from FIG. 1;

FIG. 3 shows, schematically, a view of a diagram relating to calculated voltage characteristics caused by a radial and tangential component of the magnetic flux density B of the electrical machine from FIG. 1; and

FIG. 4 shows, schematically, a view of a further diagram relating to measured voltage characteristics caused by a radial, axial and tangential component of the magnetic flux density B of the electrical machine from FIG. 1.

### DETAILED DESCRIPTION OF INVENTION

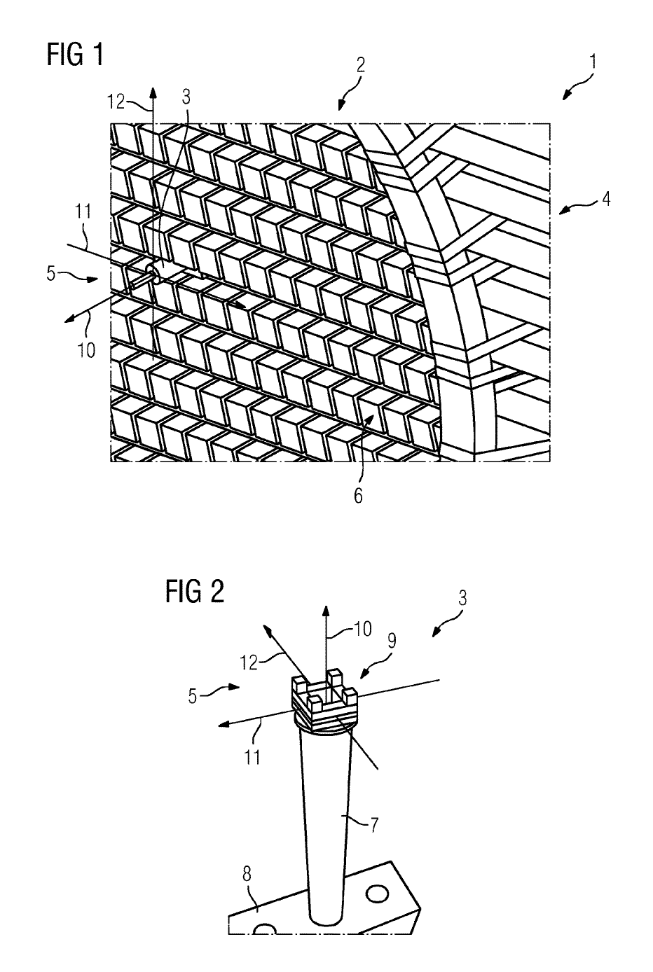

The present apparatus 1 for detecting interturn faults (not shown) inside a rotor winding (not shown) of a rotating electrical machine 2, shown only partially in FIG. 1, is shown exemplarily only with respect to its measuring device 3 (see also FIG. 2). The measuring device 3 in this case is integrated in a stator 4 of the electrical machine 2 in such a manner that the measuring device 3 projects, at least with its head part 5, over an inner surface 6 of the stator 4, into an air gap (not shown) between the inner surface 6 of the stator 4 and a circumferential surface of a rotor, not shown.

As can be seen from the representation according to FIG. 2, the head part 5 is disposed at a distance from a mounting foot element 8 of the measuring device 3 by means of a rod element 7, such that, when the measuring device 3 is properly mounted on the stator 4, it is ensured that the head part 5 is positioned inside the air gap.

In this exemplary embodiment, the head part 5 comprises a cubical element 9, on which three measuring sensors (not visible) are wound in such a manner that their respective surface vectors 10, 11 and 12 are disposed, oriented at right angles in relation to each other, on the measuring device 3.

The surface vectors 10, 11 and 12 in this case are accordingly disposed with an orientation with respect to the circumferential surface of the rotor such that a voltage induction is caused either by the radial component, the axial component or the tangential component of the magnetic flux density B, generated by the electrical machine 2, in respectively one of the measuring coils.

By means of the apparatus 1, therefore, a triaxial measurement of the magnetic flux density B of the electrical machine can be performed, and used for a subsequent analysis with respect to the detection of interturn faults.

The evaluation of the recorded, or determined, voltage characteristics in this case can be effected by means of commercially available measurement technology, but three channels are required for this.

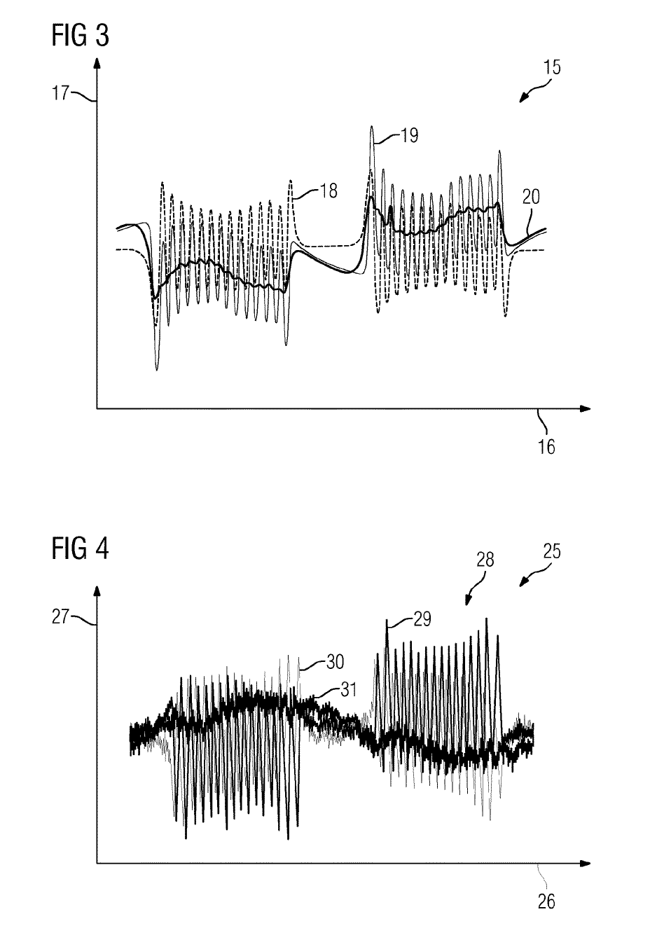

The representation according to FIG. 3 shows a diagram 15, on the abscissa 16 of which is plotted the time progression, and on the ordinate 17 of which is plotted the voltage inductions that are caused by the magnetic flux density B on the corresponding measuring coils of the measuring device 3 of the apparatus 1. Shown in this case, on the one hand, are the calculated voltage characteristic 18 caused by the tangential component of the magnetic flux density B, and, on the other hand, the calculated voltage characteristic 19 caused by the radial component of the magnetic flux density B. In addition, the voltage characteristic 20 of a radial component (tooth) is also represented.

According to the further diagram 25 shown with the representation according to FIG. 4, the time progression is plotted on the pertinent abscissa 26, and the voltage inductions are plotted on the ordinate 27 thereof. Represented on this further diagram 25 are the voltage characteristics 28, namely, of the radial voltage induction 29, the tangential voltage induction 30, and of the axial voltage induction 31, of the measuring voltages, of all three directions in space, determined by means of the measuring coils of the measuring device 3.

Although the invention has been illustrated and described in greater detail using the preferred exemplary embodiment, the invention is not limited by this disclosed exemplary embodiment, and other variations may be derived by persons skilled in the art, without departure from the protective scope of the invention.

What is claimed is:

1. An apparatus for detecting interturn faults inside a rotor winding of a rotating electrical machine by means of a measuring device, wherein the measuring device comprises
at least two measuring coils that are oriented differently in space in such a manner that, in the case of a measuring device accordingly oriented with respect to the rotor winding, a voltage induction is generated inside the first measuring coil by means of a first directional component of the magnetic flux density B of the rotating electrical machine, and a different voltage induction is generated inside the further measuring coil by means of a further directional component of this magnetic flux density B, which directional component differs from the first directional component,
wherein the at least two measuring coils that are oriented differently in space are jointly disposed on a head part of the measuring device in such a manner that interturn faults present on the rotor winding are detectable in dependence on voltage time characteristics of the voltages induced in the two measuring coils.

2. The apparatus as claimed in claim 1,
wherein a voltage induction is generated inside the first measuring coil by means of the radial component of this magnetic flux density B.

3. The apparatus as claimed in claim 1,
wherein the further measuring coil is disposed with respect to the first measuring coil in such a manner that a different voltage induction is generated inside the further measuring coil by means of the axial component of this magnetic flux density B.

4. The apparatus as claimed in claim 1,
wherein the measuring device comprises a third measuring coil that is disposed, on the head part, with respect to the first measuring coil in such a manner that a voltage induction is generated inside the third measuring coil by means of the tangential component of this magnetic flux density B.

5. The apparatus as claimed in claim 4,
wherein the measuring coils are disposed with differing orientation on the head part of the measuring device in such a manner that their surface vectors are disposed at right angles to each other.

6. The apparatus as claimed in claim 1,
wherein the measuring coils are disposed on a cubical element of the measuring device.

7. An electrical machine, comprising:
a stator and a rotor rotating therein, and
the apparatus as claimed in claim 1.

8. A method for detecting interturn faults inside a rotor winding of a rotating electrical machine, the method comprising:
generating a voltage induction inside a measuring coil disposed on a head part of a measuring device by means of the radial component of the magnetic flux density B of the rotating electrical machine,
generating a different voltage induction inside a further measuring coil disposed on the head part of the measuring device by means of the axial component of this magnetic flux density B, and
generating an additional voltage induction inside a third measuring coil disposed on the head part of the measuring device by means of the tangential component of this magnetic flux density B, and
detecting interturn faults present on the rotor winding in dependence on voltage time characteristics of voltages induced in the measuring coils.

9. The electrical machine of claim 7,
wherein the electrical machine comprises a generator.
